(19) United States
(12) Patent Application Publication
(10) Pub. No.: US 2025/0118675 A1
(43) Pub. Date: Apr. 10, 2025

(54) Modular Package of Quantum Hardware

(71) Applicant: INTERNATIONAL BUSINESS MACHINES CORPORATION, ARMONK, NY (US)

(72) Inventors: Jae-Woong NAH, Closter, NJ (US); David ABRAHAM, Croton, NY (US); John Michael COTTE, New Fairfield, CT (US); Swetha KAMLAPURKAR, Yorktown Heights, NY (US); Nicholas A. MASLUK, Putnam Valley, NY (US)

(21) Appl. No.: 18/482,843

(22) Filed: Oct. 6, 2023

(51) Int. Cl. H01L 23/538; H01L 23/00; H01L 23/13; H01L 25/00; H01L 25/065; H10N 69/00

(52) U.S. Cl. CPC H01L 23/5385; H01L 23/13; H01L 24/16; H01L 25/0655; H01L 25/50; H10D 1/20; H10D 1/692; H10N 69/00; H01L 2224/16225

(57) ABSTRACT

A modular quantum computing structure includes a plurality of attachment structures, at least some of the attachment structures having different thicknesses. At least one of a plurality of qubit chips is bonded to a first attachment structure of the plurality of attachment structures having a first thickness. A second attachment structure of the plurality of attachment structures arranged adjacent the first attachment structure has a second thickness different from the first thickness of the first attachment structure. At least one of the qubit chips bonded to the first attachment structure has a footprint extending beyond a footprint of the first interposer to overlap at least the second interposer.

### BACKGROUND

### Technical Field

The present disclosure is generally related to quantum computing hardware, and more particularly, to constructing quantum hardware with increased numbers of qubits.

### Description of the Related Art

Quantum computing is the application of quantum phenomena for information processing and communication. Various models of quantum computation exist, and the most popular models include the concepts of qubits and quantum gates. A qubit is a generalization of a bit that has two possible states, but can be in a quantum superposition of both states. A quantum gate is a generalization of a logic gate, however, the quantum gate describes the transformation that one or more qubits will experience after the gate is applied on them, given their initial state. Various quantum phenomena, such as superposition and entanglement, do not have analogs in the world of classical computing and therefore may involve special structures, techniques, and materials. As quantum computing continues to be developed, there is a desire to construct hardware with increased numbers of qubits. Most existing semiconductor devices are larger versions of the original smaller devices in which all the qubits are fabricated on a single chip.

With increased qubit counts, there is increased difficulty to fabricate quantum chips as a monolithic device. The wafer size used for increased qubit counts poses challenges in fabrication, as well as practical concerns such as tool availability, handling, or yield issues.

### SUMMARY

According to one embodiment, a modular quantum computing structure includes a plurality of attachment structures, at least some of the attachment structures are interposers having different thicknesses. At least one of a plurality of qubit chips is bonded to a first attachment structure of the plurality of attachment structures has a first thickness. A second attachment structure of the plurality of attachment structures arranged adjacent to the first attachment structure has a second thickness different from the first thickness of the first attachment structure. At least one of the qubit chips bonded to the first attachment structure has a footprint extending beyond the footprint of the first attachment structure to overlap at least the second attachment structure.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 is an overview of a modular quantum hardware structure, consistent with an illustrative embodiment.

FIG. 2A is an illustration of another modular quantum hardware package in which a first qubit chip extends beyond a footprint of a first interposer, consistent with an illustrative embodiment.

FIG. 2B is an illustration of another modular quantum hardware package having qubit chips in a stepped arrangement, consistent with an illustrative embodiment.

FIG. 3 illustrates a process flow for forming interposers with different thicknesses used in the modular quantum hardware structure, consistent with an illustrative embodiment.

FIG. 4A illustrates in an overhead view a process flow for bonding qubit chips on thicker interposers using standoffs and a modular quantum hardware package with a qubit chip bonded on a thinner interposer, consistent with an illustrative embodiment.

FIG. 4B illustrates in a perspective view the process flow for bonding qubit chips and modularity shown in FIG. 4A, consistent with an illustrative embodiment.

FIG. 5 shows a modular quantum hardware structure, consistent with an illustrated embodiment.

FIG. 6 is a flowchart illustrating a method for providing a modular quantum hardware structure, consistent with an illustrated embodiment.

### DETAILED DESCRIPTION

In the following detailed description, numerous specific details are set forth by way of examples to provide a thorough understanding of the relevant teachings. However, it is to be understood that the present teachings may be practiced without such details. In other instances, well-known methods, procedures, components, and/or circuitry have been described at a relatively high-level, without detail, to avoid unnecessarily obscuring aspects of the present teachings. It is also to be understood that the present disclosure is not limited to the depictions in the drawings, as there may be fewer elements or more elements than shown and described.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

As used herein, the term “qubit chip”, which is also sometimes referred to in the art as a quantum chip, is a component that uses the principles of quantum mechanics to perform computations.

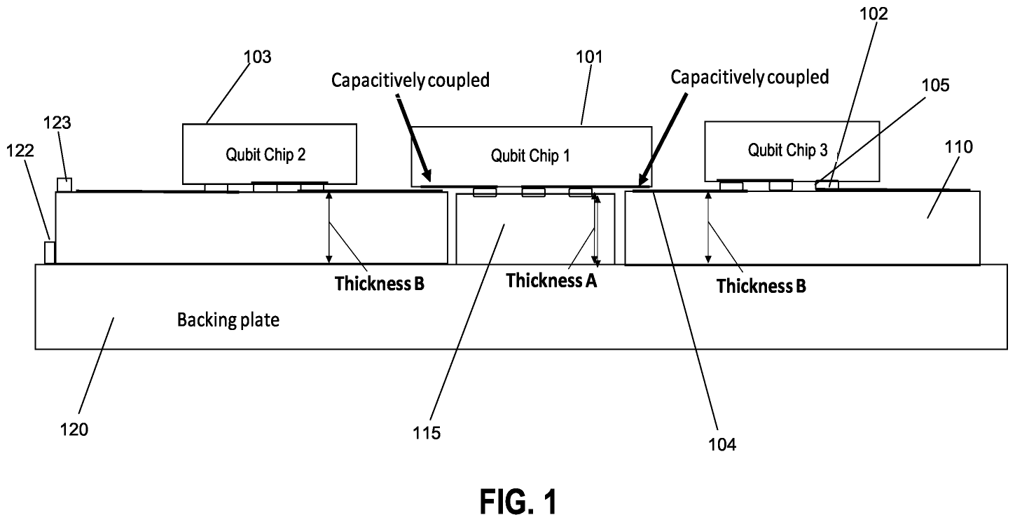

As used herein, the term “attachment structure” refers to a structure onto which a device such as a qubit chip may be attached. An attachment structure is a part of the quantum computing structure. For example, a laminate or a Printed Circuit Board (PCB) are attachment structures. In addition, if qubit chips are attached to each other (e.g., rather than being bonded to an interposer or a PCB), one of the qubit chips may be considered to be an attachment structure. For example, referring to FIG. 1, in place of the interposers 110 and 115, another qubit chip(s) may be attached to qubit chips 101 and 103 in place of the interposers. Referring to FIG. 1, the qubit chip 103 has a different thickness (taller or “thicker” than qubit chip 101). A qubit chip with a different thickness may be flipped and connected to qubit chips 101 and 103 in place of the interposers.

In contrast, a handler is a positioning tool used to hold components during construction, and a handler is not a permanent part of the quantum computing structure. An “interposer” is also a type of an attachment structure. An interposer is a structure used to connect devices to each other and a substrate or a backing plate. In quantum hardware, an interposer is an interface to accommodate and connect qubit chips and control chips. An interposer may also have multi-layer wirings (mlw) within that connect with thru-substrate vias (TSVs) to communicate with other components.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

### Technical Advantages and Support

It is to be understood that some of the advantages of the present disclosure are provided herein below. However, a person of ordinary skill in the art will appreciate that additional advantages may exist in addition to those described herein.

In an embodiment, a modular quantum computing structure includes a plurality of attachment structures, at least some of the attachment structures have a different thickness. At least one of a plurality of qubit chips is bonded to a first attachment structure of the plurality of attachment structures having a first thickness. A second attachment structure of the plurality of attachment structures adjacent to the first attachment structure, has a second thickness different from the first thickness of the first attachment structure. At least one of the qubit chips bonded to the first attachment structure has a footprint extending beyond a footprint of the first attachment structure to overlap at least the second attachment structure. An advantage of the qubit chips extending beyond a footprint of the attachment structures it is mounted on is to facilitate a coupling (capacitive or inductive) of the qubit chips to adjacent attachment structures. This arrangement of the interposers having different thicknesses may result in an increased number of qubits in quantum hardware by the modularity of smaller size qubit chips instead of forming one large size qubit chips.

In an embodiment, which may be combined with the preceding embodiment, the attachment structures are one of a laminate, a PCB, an interposer, and another qubit chip (qubit chip to qubit chips having a different thickness. The modular quantum hardware structure is not limited to a single type of attachment structure, providing for a more flexible construction.

In an embodiment, which can be combined with the preceding embodiments, the plurality of attachment structures includes a first interposer and a second interposer of a plurality of interposers, and at least another one of the plurality of qubit chips is bonded to the second interposer. The qubit chips bonded to the first interposer and the qubit chips bonded to the second interposer are bump bonded. This modular structure has qubit chips on both the first and second interposers, and the bump bonding provides a more efficient construction than other ways of bonding the qubit chips to the interposers. In addition, the modular structure having a plurality of interposers with different thicknesses allows for arrangement of an increased amount of qubit chips in the modular structure than compared with a monolithic device. In addition, the modular structure does not have the yield issues and tool availability concerns associated with a larger monolithic device.

In one or more embodiments, which can be combined with the preceding embodiments, the first interposer is thinner than the second interposer. The different thickness of the interposers provides flexibility in arranging modular quantum structures on, for example, a backing plate.

In one embodiment, which can be combined with one or more preceding embodiments, the quantum modular structure includes a backing plate. A third interposer having qubit chips bonded thereon has the same thickness as the second interposer. The first interposer is arranged on the backing plate between the second interposer and the third interposer. At least one of the qubit chips bonded to the first interposer extends beyond the footprint of the first interposer to overlap both the second interposer and the third interposer. The backing plate permits alignment of the interposers to arrange the qubits chips closer to adjacent interposers and provides for an improved yield as compared to large monolithic structures.

In one embodiment, which can be combined with one or more preceding embodiments, one or more standoffs are arranged on the surface of the second interposer and on the surface of the third interposer to maintain a uniform gap between the qubit chips on the first interposer and a surface of the second interposer and a surface of the third interposer. The standoffs facilitate controlling a gap for capacitive coupling between a qubit chip and adjacent interposers overlapped by the qubit chip.

In one embodiment, which can be combined with one or more preceding embodiments, one or more standoffs are arranged on the surface of the second interposer to maintain a uniform gap between the one or more qubit chips extending from the first interposer that overlaps the second interposer. The standoffs provide for a uniform gap between the qubit chip and adjacent interposers, which the qubit chip extends over. The uniform gap provides for more efficient capacitive or inductive coupling.

In one embodiment, which can be combined with one or more preceding embodiments, the plurality of interposers further includes solder-bonded surface mounted connectors. Surface-mounted connectors may be attached to an exterior of each of the interposers. Signal connectors may be connected to the surface mounted connectors or arranged in through-holes for signals to come in and out of the quantum structure, providing for an easier modular construction.

In one embodiment, which can be combined with one or more preceding embodiments, a plurality of modules formed by a plurality of the quantum structures are aligned to form an air-gapped connection between a qubit chip of one module and an interposer of an adjacent module of the plurality of modules. The air-gapped connection improves the capacitive coupling between the qubit chip of one module and the interposer of an adjacent module.

In one embodiment, which can be combined with one or more preceding embodiments, a bus is arranged across the air-gap connection between the qubit chip of one module and the interposer of the adjacent module of the plurality of modules. The qubit chips on one or more adjacent modules of the plurality of modules are capacitively coupled by the bus. The bus permits more efficient communication between the qubit chips.

In one embodiment, which can be combined with one or more preceding embodiments, a bus is arranged across the air-gap connection between the qubit chip of one module and the interposer of the adjacent module of the plurality of modules. The qubit chips on one or more adjacent modules of the plurality of modules are inductively coupled by the bus. The bus permits more efficient communication between the qubit chips.

In one embodiment, which can be combined with one or more preceding embodiments, the structure includes a backing plate, wherein the plurality of modules is attached to the backing plate. The backing plate provides a type of frame for arranging and aligning the modular interposers and the qubit chips bonded thereon.

In one embodiment, which can be combined with one or more preceding embodiments, the backing plate comprises an alignment ridge. The alignment ridge assists in arranging a first qubit chip and interposer on the backing plate between adjacent interposers.

In one embodiment, a modular quantum computing structure includes a plurality of interposers having three different thicknesses. A plurality of qubit chips is attached to the plurality of interposers. One or more of the plurality of qubit chips are bonded on a first interposer having a first thickness and extending beyond the footprint of the first interposer. One or more of the qubit chips bonded on the first interposer overlaps a second interposer having a second thickness. Another one or more of the plurality of the qubit chips are bonded to the second interposer. One or more of the qubit chips bonded to the second interposer overlaps a third interposer having a third thickness. The modular structure permits for more qubit chips to be arranged closer together while eliminating some of the challenges of constructing larger monolithic structures.

In an embodiment, which can be combined with the preceding embodiment, the second thickness of the second interposer and the third thickness of the third interposer are the same. This combination of interposer thicknesses permits a modular structure, where a center interposer overlaps two adjacent interposers with a uniform gap for coupling.

In one embodiment, which can be combined with one or more preceding embodiments, the structure includes standoffs arranged on the second interposer having the second thickness and on the third interposer having the third thickness. The first interposer having the first thickness is aligned between the second interposer and the third interposer on a backing plate. The standoffs facilitate controlling a gap between the first qubit chip and the second interposer to control the capacitive coupling.

In one embodiment, which can be combined with one or more preceding embodiments, the first interposer having the first thickness is thinner than the second interposer having the second thickness. The interposer having the second thickness interposer is thinner than the third interposer having the third thickness. The three thicknesses of the interposers facilitate a modular configuration that is stepped to allow for more qubit chips to be arranged on the interposers in a given area than if the interposers had the same thickness.

In one embodiment, which can be combined with one or more preceding embodiments, the structure includes a backing plate. The first interposer, the second interposer, and the third interposer are arranged on a same surface of the backing plate in a stepped arrangement based on a relative thickness of the interposers. The backing plate provides a frame for aligning and mounting the modular components.

In one embodiment, which can be combined with one or more preceding embodiments, the plurality of qubit chips is bump-bonded to the interposers. The qubit chips are attached to the interposers by bump bonding as the most efficient construction of the modular structure.

In one embodiment, which can be combined with one or more preceding embodiments, the structure includes a plurality of multi-layer wirings (MLW) arranged within the interposers. A plurality of thru-substrate vias (TSVs) are arranged within the interposers. The MLW layers are connected to the TSVs and the TSVs are connected to the qubit chips by bumps. The use of MLWs and TSVs are another way that the interposers have more bus lines in a given area.

In an embodiment, a method of constructing a modular package of quantum hardware includes grinding a first carrier wafer to a first target thickness and grinding a second carrier wafer and a third carrier wafer to a second target thickness that is thicker than the first target thickness of the first carrier wafer. A multi-layer wire (MLW) process and a thru-substrate vias (TSV) process are performed in a device wafer to form the MLWs and TSVs, and the device wafer is bonded to each of the first, second and third carrier wafers. The device wafer is ground to reveal the TSVs. After dicing into individual bonded interposer chips, the individual bonded interposer chips have sides that are aligned to a backing plate by arranging the first bonded interposer chip between the second bonded interposer chip and the third bonded interposer chip. At least one qubit chip is bump bonded to each of the device's wafer side. A portion of the qubit chip bump bonded to the first bonded interposer chip extends over at least one of the second bonded interposer chip and the third bonded interposer chip at a predetermined distance to capacitively couple the qubit chip on the first bonded interposer chip to the second bonded interposer chip and the third bonded interposer chip. The method provides for a modular construction using a plurality of interposers and qubit chips without the difficulty of an increased monolithic size and related yield and tool availability issues.

### Overview

The present disclosure is generally directed to a quantum hardware device having a modular package. The quantum structure of the present disclosure includes a plurality of qubit chips and a plurality of interposers having different thicknesses. In some embodiments, standoffs are provided on some of the interposers (e.g., adjacent interposers) to control a gap for capacitive coupling. In an embodiment, the gap for capacitive coupling of a qubit chip and an interposer is about 1 micron. The quantum hardware device may have a gap for capacitive coupling ranging from 0.3 microns to 30 microns, which can depend on the different thicknesses of the plurality of the interposers arranged with the qubit chips. A capacitive coupling below 0.3 poses challenges due to a number of issues including roughness of the substrates, particulate in the way preventing that gap from being obtained, mechanical tolerances required to guarantee such a gap, etc. Spacing beyond a 30-micron gap for capacitive coupling may be too weak for effective signal transfer. The capacitive coupling range may be applicable to construction with as well as without the use of standoffs.

The concepts herein relate to quantum technology and quantum hardware. Regarding quantum technology, the electromagnetic energy associated with a qubit can be stored, for example, in so-called Josephson junctions and in the capacitive and inductive elements that are used to form the qubit. In other examples, there may be spin qubits coupled to resonators or topological qubits, microfabricated ion traps, etc. Other types of superconducting components are supported by the teachings herein as well, including (without limitation), circulators, isolators, amplifiers, filters, active control electronics such as rapid single flux quantum (RSFQ), etc.

In one example, to read out the qubit state, a microwave signal is applied to the microwave readout cavity that couples to the qubit at the cavity frequency. The transmitted (or reflected) microwave signal goes through multiple thermal isolation stages and low-noise amplifiers that are used to block or reduce the noise and improve the signal-to-noise ratio. The amplitude and/or phase of the returned/output microwave signal carries information about the qubit state, such as whether the qubit has dephased to the ground or excited state. The microwave signal carrying the quantum information about the qubit state is usually weak (e.g., on the order of a few microwave photons). Various circuits and techniques can be used to measure this weak signal. For example, low-noise quantum-limited amplifiers (QLAs), such as Josephson amplifiers and travelling-wave parametric amplifiers (TWPAs), may be used as preamplifiers at the output of the quantum system to boost the quantum signal, while adding a very little (e.g., minimal) amount of noise as dictated by quantum mechanics, in order to improve the signal to noise ratio of the output chain. In addition to Josephson amplifiers, certain Josephson microwave components that use Josephson amplifiers or Josephson mixers such as Josephson circulators, Josephson isolators, and Josephson mixers can be used in scalable quantum processors.

A qubit system may include one or more readout resonators coupled to the qubit. A readout resonator may be a transmission line that includes a capacitive connection to the ground on one side and is either shorted to the ground on the other side, such as for a quarter wavelength resonator, or may have a capacitive connection to the ground, such as for a half wavelength resonator, which results in oscillations within the transmission line, with the resonant frequency of the oscillations being close to the frequency of the qubit. For example, the readout resonator affects a pulse coming from the control/measurement instruments at the readout resonator frequency. The pulse acts as a measurement that decoheres the qubit and makes it collapse into a state of “one” or “zero,” thereby imparting a phase shift on that measurement pulse.

Between qubits there may be a coupling resonator, which allows coupling different qubits together in order to realize quantum logic gates. The coupling resonator is typically structurally similar to the readout resonator in that it is a transmission line that includes capacitive connections to the ground on both sides, which also results in oscillations within the coupling resonator. When a qubit is implemented as a transmon, each side of the coupling resonator is coupled (e.g., capacitively or inductively) to a corresponding qubit by being in adequate proximity to (e.g., the capacitor of) the qubit. Since each side of the coupling resonator has coupled with a respective different qubit, the two qubits are coupled together through the coupling resonator. In this way, there is mutual interdependence in the state between coupled qubits, thereby allowing a coupling resonator to use the state of one qubit to control the state of another qubit. Entanglement occurs when the interaction between two qubits is such that the states of the two cannot be specified independently, but can only be specified for the whole system. In this way, the states of two qubits are linked together such that a measurement of one of the qubits, causes the state of the other qubit to collapse.

Typical materials to make the interconnects include, without limitation, niobium (Nb), aluminum (Al), niobium nitride (NbN), titanium nitride (TiN), niobium titanium nitride (NbTiN), etc., sometimes referred to herein as superconductors. It will be understood that other suitable materials that have superconducting properties can be used as well.

Quantum technology is still a developing field and providing structures with highly predictable and more ideal performance is a challenge. In quantum computing, there is a desire for structures with larger quantities of qubits. Conventional construction has been making larger and larger monolithic structures to accommodate the increased quantities of qubit chips. However, tool availability and yield issues are just some of the difficulties encountered by increasing the size of monolithic structures to accommodate the larger quantities of qubit chips.

FIG. 1 is an overview of a modular quantum hardware structure, consistent with an illustrative embodiment. It is shown in FIG. 1 a first qubit chip 101, a second qubit chip 103 and a third qubit chip 105. The second qubit chip 103 and the third qubit chip 105 are bump bonded on interposers 110 having a first thickness. In this embodiment, the first qubit chip 101 is bonded on an interposer 115 by solder bumps 102. The quantum hardware of the present disclosure is not limited to bump bonding. The first qubit chip 101, second qubit chip 103, and third qubit chip 105 communicate via buses 104. An alignment ridge 122 assists in arranging the first qubit chip 101 and interposers 110 on the backing plate 120 between adjacent interposers. One or more surface mounted connectors 123 are arranged on the interposers to connect signal connectors (not shown) from external devices.

It can be seen that the first interposer 115 is thinner than the second interposers 110 shown on the left side and the right side of qubit chip 101. In addition, the footprint of qubit chip 101 extends over the footprint of the first interposer 115 so as to overlap the two adjacent second interposers 110. This structure permits capacitive coupling between the first qubit chip 101 and the second interposers 110 as shown. The first interposers 115 and the second interposers 115 are arranged on the backing plate 120. It is to be understood that the examples of different thicknesses are provided for illustrative purposes, the modular quantum structure of the present disclosure is not limited in the thickness of the interposers shown in FIG. 1.

### Example Embodiment(s)

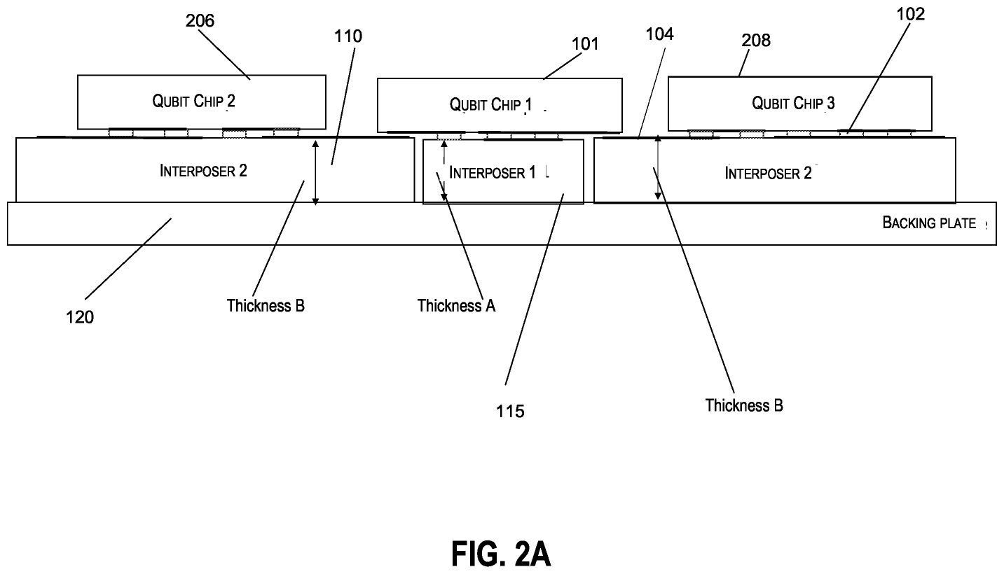

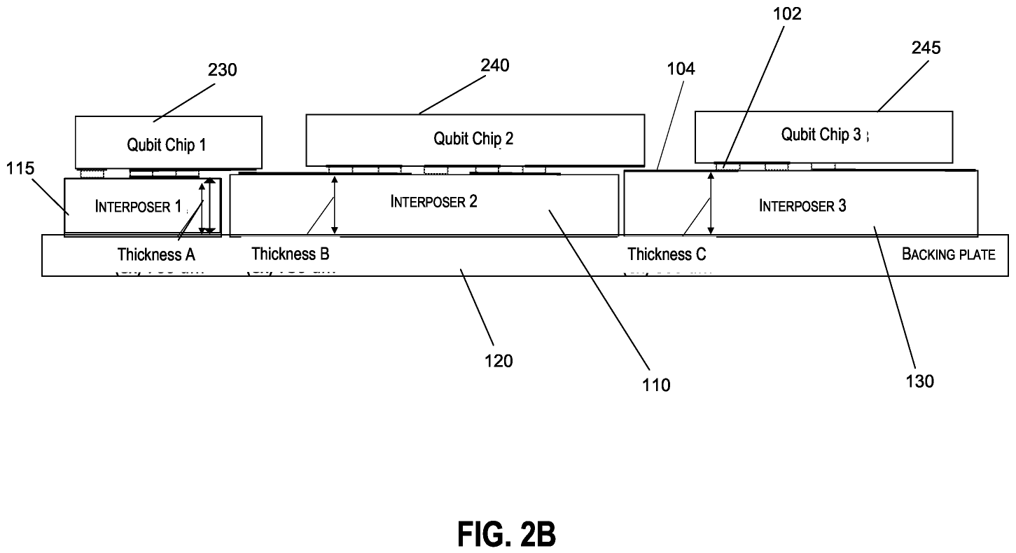

FIG. 2A is an illustration of another modular quantum hardware package in which a first qubit chip that extends beyond a footprint of a first interposer, consistent with an illustrative embodiment. The qubit chips 206, 208 shown in FIG. 2A are larger than shown in FIG. 1 and have more bump bonds than FIG. 1. The example thicknesses of the first interposer 115 and the second interposers 110 are similar to the structure shown in FIG. 1.

FIG. 2B is an illustration of another modular quantum hardware package having qubit chips in a stepped arrangement, consistent with an illustrative embodiment. In FIG. 2B, the bump bonds of the qubit chips are offset from the bump bonds of the qubit chips of the FIGS. 1 and 2A. The illustration in FIG. 2B has one second interposer 110 and a third interposer 130. The un-centered (e.g., offset) position of the bump bonds used to attach the qubit chips to the interposer results in an area of the qubit chip that can overlap an adjacent interposer. For example, the qubit chip 230 overlaps the second interposer 110, and qubit chip 240 overlaps the third interposer 130. The third interposer 130 has a different thickness than both of the first interposer 115 and the second interposer 110. The qubit chip 245 may have a similar offset construction with regard to bump bonds, but in this embodiment, the qubit chip 245 does not extend beyond a footprint of the third interposer 130. As previously discussed, the overlap of the qubit chip facilitates capacitive coupling with connections of an adjacent interposer (e.g., 110, 130 in FIG. 2B).

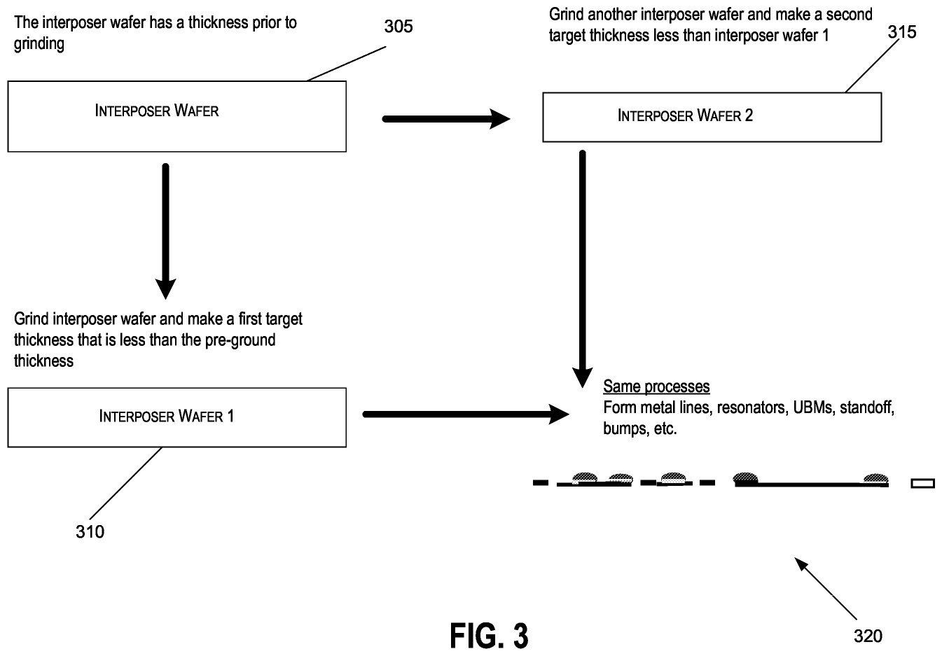

FIG. 3 illustrates a process flow for forming interposers with different thicknesses used in the modular quantum hardware structure, consistent with an illustrative embodiment. It is to be understood that interposers for a modular quantum structure are not limited to the form shown and described in FIG. 3. An initial interposer wafer 305 has a predetermined tolerance of thickness so it can be ground into a various target thickness. The interposer wafers 310 and 315 are then processed by providing one or more of metal lines, resonators, under bump metallurgy (UBMs), standoffs, bumps, etc. to facilitate the bonding of qubit chips onto the interposers.

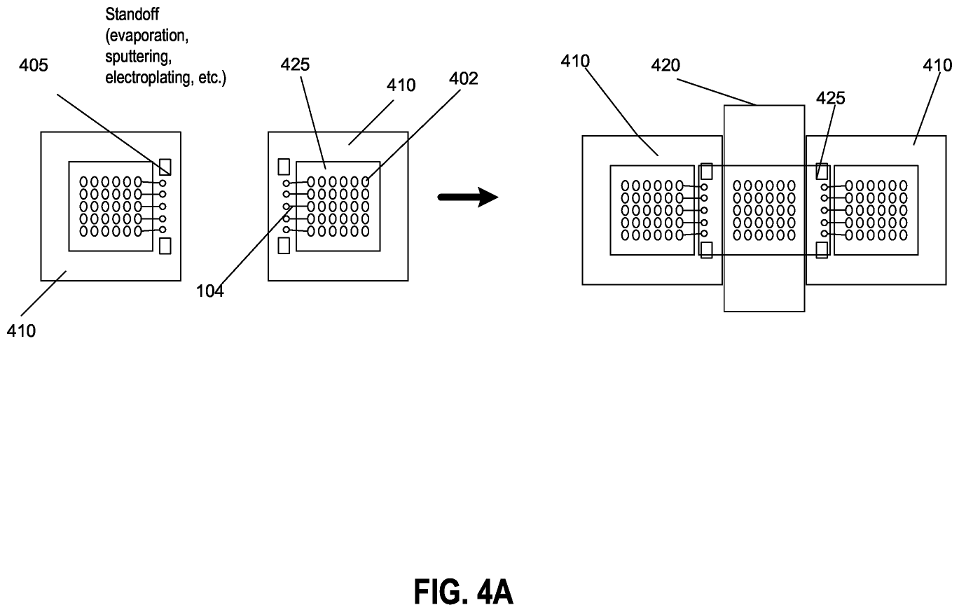

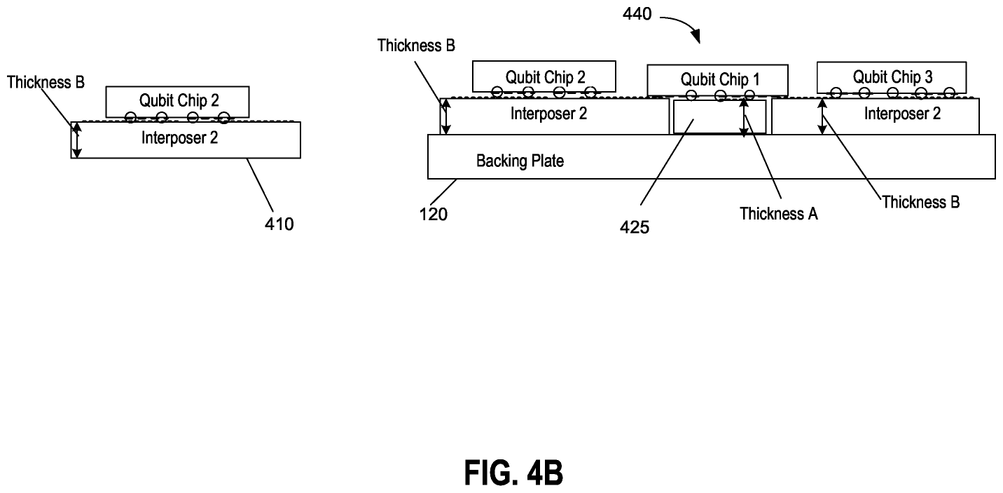

FIG. 4A in an overhead view illustrates a process flow for bonding qubit chips on thicker interposers with standoffs and a modular quantum hardware package with a qubit chip bonded on a thinner interposer, consistent with an illustrative embodiment. FIG. 4B illustrates the process flow of FIG. 4A in a perspective view. Referring to FIGS. 4A and 4B, in addition to an array of bumps 402 for bonding the qubit chips to another structure such as an interposer there are standoffs 405 that may be formed by evaporation, sputtering, electroplating, etc., on edges of the adjacent interposers 410 relative to a center interposer 420. One or more buses 104 such as shown in FIG. 1 provide signal connections to other components including but not limited to qubit chips. The adjacent interposers 410 are the thicker interposers compared to the center interposer 420. The center interposer 420 is arranged on the backing plate with thicker interposers 410 and a qubit chip 425 is bump bonded so that the standoffs maintain a uniform gap between the qubit chip 425, and the adjacent interposers 410 to facilitate coupling between the qubit chip 425 and the adjacent interposers 410. A cross-sectional view of the interposer 410 and the qubit chip is shown in FIG. 4B, and a cross-sectional view of the modular structure 440 is shown after the modular fabrication is performed.

It is to be understood that various types of quantum hardware in addition to the examples shown and described above may be constructed in accordance with the teachings of the present disclosure.

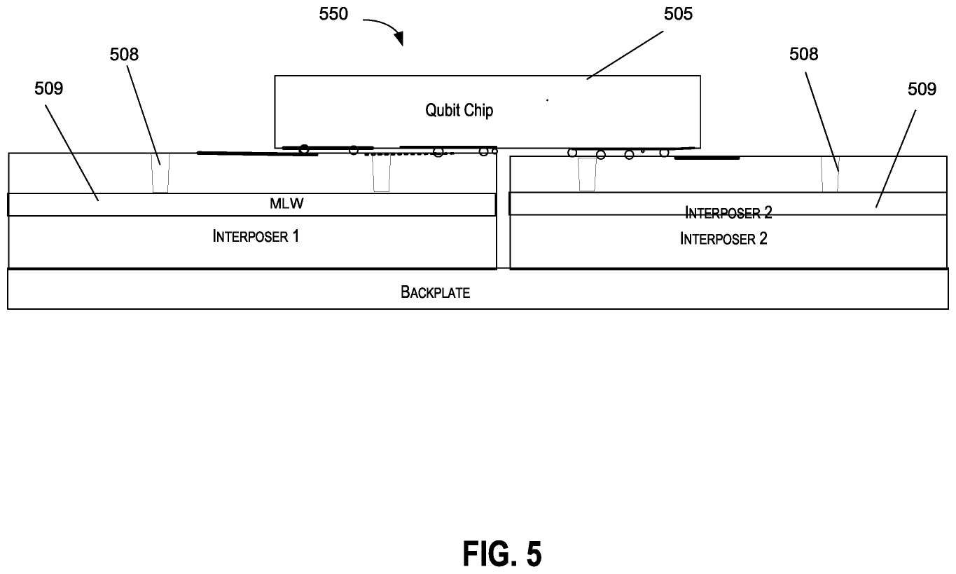

FIG. 5 shows a modular quantum hardware structure, consistent with an illustrated embodiment. The quantum hardware structure 550 may optionally include thru-substrate vias (TSVs) 508 and multi-layer wirings (MLW) layers 509. Qubit chip 505 overlaps adjacent interposers of different thicknesses and is bump bonded to the adjacent interposers, having bump bonded thereon. The TSVs 508 and the MLWs 509, which are formed within the interposers, and the TSVs are used to provide signals between the MLWs 509 and the qubit chips. It is to be understood that additional qubit chips may be attached to the interposers, and as the arrangement is modular, there may be additional interposers attached to the backplate having thicknesses adjacently arranged in various combinations.

### Example Process

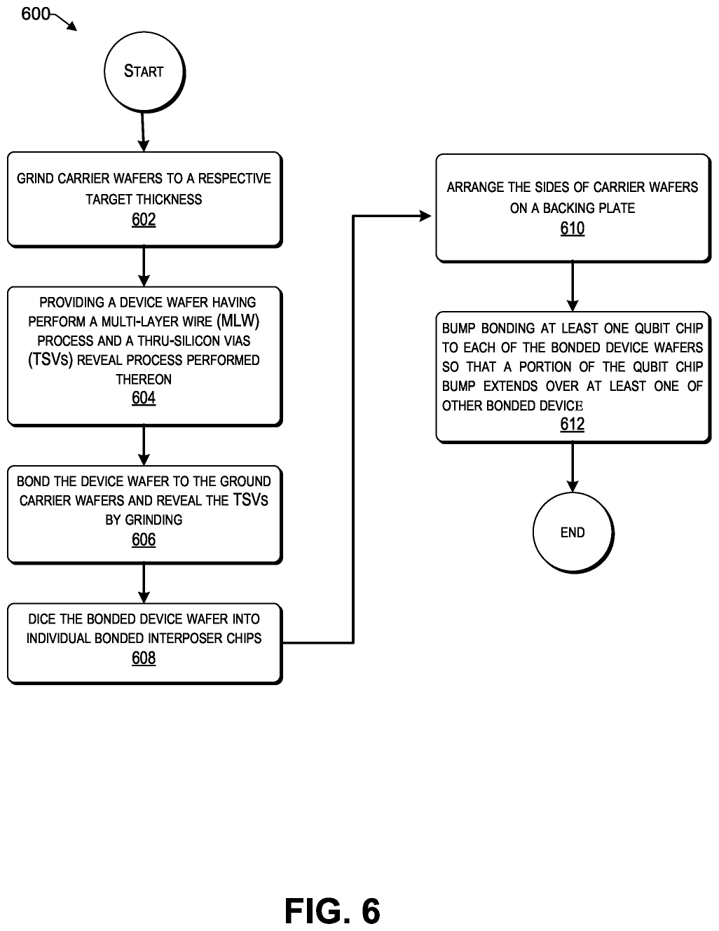

With the foregoing overview of the example architecture, it may be helpful now to consider a high-level discussion of an example process. To that end, FIG. 6 is a flowchart illustrating a method of constructing a modular quantum hardware structure consistent with an illustrative embodiment.

Carrier wafers are each ground to a respective target thickness (operation 602). For example, a first carrier wafer is ground to a first target thickness, a second carrier wafer is ground to a second target thickness. The second target thickness is thicker or thinner than the first target thickness of the first carrier wafer. Optionally, a third carrier wafer may be ground to the same thickness as the second carrier wafer (see FIG. 2A), or the third carrier wave may be ground to a different thickness than the first carrier wafer and the second carrier wafer (see FIG. 2B).

A multi-layer wire (MLW) process and a thru-substrate vias (TSVs) reveal process is performed on the device wafer (operation 604). It is to be understood that construction of the modular quantum hardware structure according to the present disclosure may be made without TSVs and MLWs (such as shown in FIG. 1), and the operation to include TSV and MLWs is optional.

The device wafer is bonded to the ground carrier wafers and the TSVs are revealed by grinding (operation 606). The bonding may be performed by an adhesive. The revealing of the TSV is performed by exposing the TSV (typically on a backside) of the ground carrier wafer. The TSV may provide signal passage from a multi-layer wiring to the top of the ground carrier wafer and the qubit chips.

The bonded device wafer from operation 608 is diced into individual bonded interposer chips (operation 610). The individual interposer chips may have different thicknesses.

The carrier wafers are arranged on a backing plate (operation 610). For example, a first bonded interposer chip may be arranged on the backing plate between a second bonded interposer chip and a third bonded interposer chip (such as shown in FIG. 1). Each bonded interposer chip is a diced portion of the device wafer bonded to the ground carrier wafer from operation 608. The bonded interposer chips with MLWs and TSV is not any particular thickness. However, for explanatory purposes, the device wafer may be about 100 μm and when adhered to the ground carrier wafer and then diced, results in a bonded interposer chip thicker than the ground carrier wafer alone by about 100 μm (in this example). It is to be understood that the modular quantum hardware structure is not limited to the thickness disclosed herein for explanatory purposes.

At least one qubit chip is bump bonded to each of the bonded interposer chips, so that a portion of the qubit chip extended over at least one other bonded device (operation 612). The lower portion of the qubit chip overhangs the other bonded device at a predetermined distance so that the qubit chip bonded on the first bonded interposer chip is capacitively coupled to the second bonded interposer chip (and the third bonded interposer chip in the case where the qubit chip overhangs part of the third bonded interposer chip).

The method ends at operation 612. It is to be understood that the carrier wafer as discussed herein may be substituted with a glass wafer, a metal, a ceramic, etc.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to better explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A modular quantum computing structure, comprising:
a plurality of qubit chips;
a plurality of attachment structures, wherein at least some of the attachment structures have a different thickness;
at least one qubit chip of the plurality of qubit chips is bonded to a first attachment structure of the plurality of attachment structures having a first thickness; and
a second attachment structure of the plurality of attachment structures adjacent the first attachment structures, wherein:
the second attachment structure has a second thickness different from the first thickness of the first attachment structure; and
the at least one of the plurality of qubit chips bonded to the first attachment structures extends beyond a footprint of the first attachment structure so the at least one of the qubit chips overlaps at least the second attachment structures.

2. The modular quantum computing structure according to claim 1, wherein the plurality of attachment structures are selected from the group consisting of a laminate, a PCB, an interposer, and another qubit chip.

3. The modular quantum computing structure according to claim 1, wherein the plurality of attachment structures comprise a first interposer and a second interposer of a plurality of interposers, and
wherein at least another one of the plurality of qubit chips is bonded to the second interposer, and wherein the qubit chips bonded to the first interposer and the qubit chips bonded to the second interposer are bump bonded.

4. The modular quantum computing structure according to claim 3, wherein the first interposer is thinner than the second interposer.

5. The modular quantum computing structure according to claim 4, further comprising:
a backing plate; and
a third interposer having qubit chips bonded thereon, wherein:
the third interposer has a thickness that is the same as the second interposer;
the first interposer is arranged on the backing plate between the second interposer and the third interposer; and
the at least one of qubit chips bonded to the first interposer extends beyond the footprint of the first interposer to overlap both the second interposer and the third interposer.

6. The modular quantum computing structure according to claim 5, further comprising one or more standoffs arranged on an upper surface of the second interposer and on an upper surface of the third interposer, wherein the one or more standoffs are sized to provide a uniform gap between the qubit chips on the first interposer and the upper surfaces of the second and third interposers.

7. The modular quantum computing structure according to claim 3, further comprising one or more standoffs arranged on a surface of the second interposer and configured to maintain a uniform gap between the qubit chips extending from the first interposer that overlaps the second interposer.

8. The modular quantum computing structure according to claim 3, wherein the plurality of interposers further includes solder-bonded surface mounted connectors.

9. The modular quantum computing structure according to claim 3, further comprising a plurality of modules formed by a plurality of quantum computing structures aligned to form an air-gapped connection between a qubit chip of the plurality of qubit chips of one module and an interposer of an adjacent module of the plurality of modules.

10. The modular quantum computing structure according to claim 9, further comprising a bus across the air-gap connection between the qubit chip of the one module and the interposer of the adjacent module of the plurality of modules, wherein one or more qubit chips on one or more adjacent modules of the plurality of modules are capacitively coupled by the bus.

11. The modular quantum computing structure according to claim 9, further comprising a bus across the air-gap connection between the qubit chip of one module and the interposer of the adjacent module of the plurality of modules, wherein the plurality of qubit chips bonded on one or more adjacent modules of the plurality of modules are inductively coupled by the bus.

12. The modular quantum computing structure according to claim 9, further comprising a backing plate, wherein the plurality of modules is attached to the backing plate, and wherein the backing plate includes an alignment ridge.

13. An electronic structure comprising:
a plurality of interposers, each interposer having a different thicknesses;
a plurality of qubit chips attached to the plurality of interposers;
one or more of the plurality of qubit chips bonded on a first interposer having a first thickness and extending beyond a footprint of the first interposer, wherein at least one of the qubit chips bonded on the first interposer overlaps a second interposer of the plurality of interposers; and
another one or more of the plurality of the qubit chips bonded on the second interposer having a second thickness, wherein at least one of the qubit chips bonded on the second interposer overlaps a third interposer having a third thickness.

14. The electronic structure according to claim 13, wherein the second thickness of the second interposer and the third thickness of the third interposer are the same.

15. The electronic structure according to claim 14, further comprising metal standoffs arranged on the second interposer having the second thickness and on the third interposer having the third thickness, wherein the first interposer having the first thickness is aligned between the second interposer and the third interposer on a backing plate.

16. The structure according to claim 13, wherein:
the first interposer having the first thickness is thinner than the second interposer having the second thickness; and
the second interposer having the second thickness is thinner than the third interposer having the third thickness.

17. The electronic structure according to claim 13, further comprising a backing plate, wherein the first interposer, the second interposer, and the third interposer are arranged on a same surface of the backing plate in a stepped arrangement based on a relative thickness of the interposers.

18. The electronic structure according to claim 13, wherein each of the plurality of qubit chips is bump bonded to the interposers.

19. The electronic structure according to claim 13, further comprising:
a plurality of multi-layer wirings (MLW) arranged within the interposers; and
a plurality of thru-substrate vias (TSVs) arranged within the interposers,
wherein the MLW layers are connected to the TSVs and the TSVs to connected to the qubit chips.

20. A method of constructing a modular package of quantum hardware, the method comprising:
grinding a first carrier wafer to a first target thickness;
grinding a second carrier wafer and a third carrier wafer to a second target thickness that is thicker than the first target thickness of the first carrier wafer;
providing a device wafer having a multi-layer wire (MLW) formed by an MLW process and a thru-substrate vias (TSVs) formed thereon by a reveal process;
bonding the device wafer to the first, second, and third carrier wafers having respective target thicknesses and revealing the TSVs by grinding;
dicing the bonded device wafer into individual interposer chips;
arranging a side of each of the ground carrier wafers on a backing plate by arranging a first bonded interposer chip between a second bonded interposer chip and a third bonded interposer chip; and
bump bonding at least one qubit chip to each of the bonded interposer chips, wherein:
a portion of the qubit chip that is bump bonded to the first bonded interposer chip extends over at least one of the second bonded interposer chip and the third bonded interposer chip at a predetermined distance; and
the qubit chip bonded on the first bonded interposer chip is capacitively coupled to the second bonded interposer chip and the third bonded interposer chip.
